(19) United States
(12) Patent Application Publication
(10) Pub. No.: US 2009/0158131 A1
(43) Pub. Date: Jun. 18, 2009

(54) VITERBI DECODING APPARATUS AND METHOD

(75) Inventors: Sung Woo CHOI, Daejeon (KR); Kyu-Min Kang, Daejeon (KR); Sang Sung Choi, Daejeon (KR); Kwang Roh Park, Daejeon (KR)

Correspondence Address: STAAS & HALSEY LLP, SUITE 700, 1201 NEW YORK AVENUE, N.W., WASHINGTON, DC, 20005, US

(73) Assignee: ELECTRONICS AND TELECOMMUNICATIONS RESEARCH INSTITUTE, Daejeon (KR)

(21) Appl. No.: 12/188,416

(22) Filed: Aug. 8, 2008

(30) Foreign Application Priority Data
Dec. 13, 2007 (KR) 10-2007-0130384

(51) Int. Cl. H03M 13/03; G06F 11/10

(52) U.S. Cl. 714/795; 714/E11.032

(57) ABSTRACT

A Viterbi decoding apparatus receives a plurality of block data in time order, and transmits a block data group including the plurality of block data. Then, the Viterbi decoding apparatus applies a Viterbi decoding algorithm to the block data group and outputs some block data of the block data group. In this way, it is possible to provide a Viterbi decoding apparatus that can operate at a high speed and improve a data transmission rate.

### CROSS-REFERENCE TO RELATED APPLICATION

This application claims priority to and the benefit of Korean Patent Application No. 10-2007-0130384 filed in the Korean Intellectual Property Office on Dec. 13, 2007, the entire contents of which are incorporated herein by reference.

### BACKGROUND OF THE INVENTION

(a) Field of the Invention

The present invention relates to a Viterbi decoding method and apparatus. Particularly, the present invention relates to a Viterbi decoding method and apparatus in an ultra-wideband system.

The present invention was supported by the IT R&D program of MIC/IITA [2006-S-071-02, Development of USB solution for High-speed Multimedia Transmission].

(b) Description of the Related Art

Convolutional codes have been commonly used as channel codes for correcting transmission errors during wire/wireless data communication, and Viterbi decoders have been generally used to decode data with channels that are encoded by these convolutional codes. The Viterbi decoder has advantages in that it has high performance and a simple hardware structure.

However, it is difficult for the existing Viterbi decoder to operate at a high speed in a communication system requiring a high-speed operation, and it is difficult to improve a data transmission rate.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a Viterbi decoding apparatus that can operate at a high speed and improve a data transmission rate.

According to an aspect of the invention, a Viterbi decoding method includes: receiving a plurality of block data in time order; transmitting a first block data group including the plurality of block data; applying a Viterbi decoding algorithm to the first block data group and outputting some block data of the first block data group; receiving a plurality of additional block data connected with the plurality of block data in time order; transmitting a second block data group including the plurality of additional block data and some block data of the first block data group; and applying the Viterbi decoding algorithm to the second block data group and outputting some block data of the second block data group.

The receiving of the plurality of block data may include receiving an even number of block data in time order, and the receiving of the plurality of additional block data may include receiving an even number of additional block data in time order.

The even number of block data may be four block data, the even number of additional block data may be two additional block data, and the second block data group may include two of the four block data and the two additional block data.

The second block data group may include two of the four block data that are received late in time order.

The outputting of some block data of the first block data group may include outputting the second block data and third block data of the first block data group that are received in time order.

The outputting of some block data of the second block data group may include outputting the second block data and the third block data of the second block data group that are received in time order.

The Viterbi decoding algorithm may be a block processing Viterbi decoding algorithm.

According to another aspect of the invention, there is provided a Viterbi decoding apparatus that receives data from a depuncturer including two memory buffers and outputting the data from the depuncturer using output clocks which is equal to or higher than input clocks, and performs decoding. The Viterbi decoding apparatus includes a distributor, a plurality of memory banks, a plurality of switches, and a plurality of decoders. The distributor receives a plurality of bits from the depuncturer, and distributes the received plurality of bits to each block data unit. The plurality of memory banks receive block data corresponding to some of the plurality of bits from the distributor in a predetermined order, and store the received block data. The plurality of switches are connected to some of the plurality of memory banks, and output the block data stored in one of the connected memory banks. The plurality of decoders are connected to some of the plurality of switches, receive a plurality of block data from the connected switches, process the plurality of block data according to a Viterbi decoding algorithm, and output some of the plurality of block data.

Some or all of the plurality of decoders may be used according to the number of bits simultaneously inputted to the distributor.

The plurality of memory banks may be an even number of memory banks, and the plurality of switches may be an even number of switches. Odd-numbered switches of the even number of switches may be connected in parallel to odd-numbered memory banks of the even number of memory banks, and even-numbered switches of the even number of switches may be connected in parallel to even-numbered memory banks of the even number of memory banks.

The plurality of decoders may be sliding block Viterbi decoders using a block processing Viterbi decoding method.

The plurality of memory banks may include eight memory banks, the plurality of switches may include eight switches, and the plurality of decoders may include two decoders.

Each of the two decoders may have transmission capacity that is half the maximum transmission capacity of the Viterbi decoding apparatus.

The Viterbi decoding apparatus according to the above-mentioned aspect of the invention can operate at a high speed using a block processing decoding method and improve a data rate. Further, it is possible to control the operation of the Viterbi decoding apparatus according to a data rate and thus reduce power consumption.

### BRIEF DESCRIPTION OF THE DRAWINGS

FIG. 1 is a diagram illustrating the structure of transmitting/receiving apparatuses of an ultra-wideband system following an MB-OFDM scheme according to an exemplary embodiment of the present invention.

FIG. 2 is a diagram illustrating the input and output of a depuncturer when the data rate of the ultra-wideband system according to the exemplary embodiment of the present invention is 53.3 Mbps.

FIG. 3 is a diagram illustrating the input and output of the depuncturer when the data rate of the ultra-wideband system according to the exemplary embodiment of the present invention is 480 Mbps.

FIG. 4 is a diagram illustrating the input and output of the depuncturer when the data rate of the ultra-wideband system according to the exemplary embodiment of the present invention is 960 Mbps.

FIG. 5 is a diagram illustrating the structure of a Viterbi decoding unit according to the exemplary embodiment of the present invention.

FIG. 6 is a diagram illustrating the operation of the Viterbi decoding unit decoding depunctured data when the data rate of the ultra-wideband system according to the exemplary embodiment of the present invention is 480 Mbps or less.

FIG. 7 is a diagram illustrating the operation of the Viterbi decoding unit decoding the depunctured data when the data rate of the ultra-wideband system according to the exemplary embodiment of the present invention is more than 480 Mbps.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

It will be understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. In addition, the terms “-er”, “-or”, and “module” described in the specification mean units for processing at least one function and operation and can be implemented by hardware components or software components and combinations thereof.

Hereinafter, a Viterbi decoding method and apparatus according to exemplary embodiments of the present invention will be described with reference to the accompanying drawings.

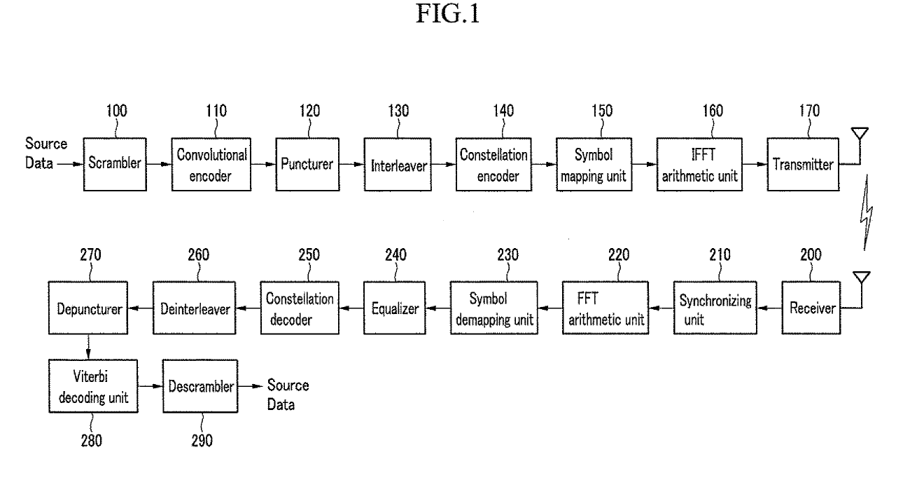

First, transmitting/receiving apparatuses of an ultra-wideband system following a multi-band orthogonal frequency division multiplexing (MB-OFDM) scheme according to an exemplary embodiment of the present invention will be described with reference to FIGS. 1 to 4.

FIG. 1 is a diagram illustrating the structure of the transmitting/receiving apparatuses of the ultra-wideband system following the MB-OFDM scheme according to the exemplary embodiment of the present invention.

As shown in FIG. 1, the transmitting apparatus of the ultra-wideband system according to the exemplary embodiment of the present invention includes a scrambler 100, a convolutional encoder 110, a puncturer 120, an interleaver 130, a constellation encoder 140, a symbol mapping unit 150, an inverse Fast Fourier transform (IFFT) arithmetic unit 160, and a transmitter 170.

The scrambler 100 receives source data composed of a plurality of bits, scrambles the source data, and outputs the scrambled data.

The convolutional encoder 110 encodes the scrambled data using convolution codes and outputs the encoded data.

The puncturer 120 punctures the encoded data, that is, converts a data coding rate, and outputs the punctured data. In this case, the ultra-wideband system has a basic data coding rate of ⅓, and the puncturer 120 punctures the encoded data having the basic data coding rate and outputs the punctured data having a data coding rate of ½, ⅝, or ¾.

The interleaver 130 interleaves the punctured data, and outputs the interleaved data. The interleaved data is composed of a plurality of bits.

The constellation encoder 140 encodes the interleaved data and outputs a plurality of symbols. The constellation encoder 140 may encode the interleaved data using a quadrature phase shift keying (QPSK) method, a dual carrier modulation (DCM) method, or a 16-quadrature amplitude modulation (16-QAM) method.

The symbol mapping unit 150 maps a plurality of symbols, and outputs a plurality of frequency domain symbols. The symbol mapping unit 150 may map a plurality of symbols to a plurality of frequency domain symbols using time spread or frequency spread effects.

The IFFT arithmetic unit 160 performs inverse fast Fourier transform (IFFT) on a plurality of frequency domain symbols and outputs orthogonal frequency division multiplexing (OFDM) signals.

The transmitter 170 transmits the OFDM signals to the receiving apparatus through an antenna. The transmitter 170 may convert digital OFDM signals into analog OFDM signals, amplify the analog OFDM signals, and transmit the amplified signals.

The data rates supported by the ultra-wideband system according to the exemplary embodiment of the present invention are shown in Table 1.

TABLE 1

| | | | Encoded | | |
|---|---|---|---|---|---|
| Data rate | Modulation | Coding | bit/6 OFDM | Frequency | Time |
| (Mbps) | method | rate | symbols | spreading | spreading |
| 53.3 | QPSK | ⅓ | 300 | YES | YES |
| 80 | QPSK | ½ | 300 | YES | YES |
| 106.7 | QPSK | ⅓ | 600 | NO | YES |
| 160 | QPSK | ½ | 600 | NO | YES |
| 200 | QPSK | ⅝ | 600 | NO | YES |
| 320 | DCM | ½ | 1200 | NO | NO |
| 400 | DCM | ⅝ | 1200 | NO | NO |
| 480 | DCM | ¾ | 1200 | NO | NO |
| 640 | 16QAM | ½ | 2400 | NO | NO |
| 800 | 16QAM | ⅝ | 2400 | NO | NO |
| 960 | 16QAM | ¾ | 2400 | NO | NO |

As shown in Table 1, a modulation method, a coding rate, encoded bits per 6 OFDM symbols, the decision of whether to perform frequency spreading, and the decision of whether to perform time spreading depend on the data rate.

As shown in FIG. 1, the receiving apparatus of the ultra-wideband system according to the exemplary embodiment of the present invention includes a receiver 200, a synchronizing unit 210, a fast Fourier transform (FFT) arithmetic unit 220, a symbol demapping unit 230, an equalizer 240, a constellation decoder 250, a deinterleaver 260, a depuncturer 270, a Viterbi decoding unit 280, and a descrambler 290.

The receiver 200 receives the OFDM signal transmitted from the transmitting apparatus. The receiver 200 may amplify the received OFDM signal and convert analog OFDM signals into digital OFDM signals.

The synchronizing unit 210 synchronizes the received OFDM signal and outputs the synchronized OFDM signal. The synchronizing unit 210 may perform frame synchronization for detecting the start of a signal, symbol synchronization for detecting the start of a symbol, and frequency synchronization for finding a phase error.

The FFT arithmetic unit 220 performs fast Fourier transform (FFT) on the synchronized OFDM signal, and outputs a plurality of frequency domain symbols.

The symbol demapping unit 230 demaps the plurality of frequency domain symbols and outputs a plurality of symbols. The symbol demapping unit 230 may effectively remove time spread and frequency spread to demap a plurality of frequency domain symbols into a plurality of symbols.

The equalizer 240 equalizes the channels of a plurality of symbols and outputs a plurality of channel-equalized symbols.

The constellation decoder 250 decodes the plurality of channel-equalized symbols and outputs decoded data including a plurality of bits. The constellation decoder 250 may perform soft decision decoding on the plurality of channel-equalized symbols and output decoded data.

The deinterleaver 260 deinterleaves the decoded data and outputs deinterleaved data including a plurality of bits. The deinterleaver 260 includes two memory blocks, performs reading in one of the memory blocks, and performs writing in the other memory block. Since the deinterleaver 260 has two memory blocks, it can make an input clock different from an output clock.

The depuncturer 270 depunctures the deinterleaved data and outputs depunctured data including a plurality of bits. The depuncturer 270 has a dual buffer structure that uses two memory buffers. The depuncturer 270 may use different input and output clocks, and selects different input and output bits. The output of the deinterleaver 260 and the output of the depuncturer 270 depending on the data rate are shown in Table 2.

(Table 2)

TABLE 2

| | Output of deinterleaver | | | Output of depuncturer | | |
|---|---|---|---|---|---|---|
| | | | Number | | | Number |
| Data rate | Clock | Number | of | Clock | Number | of |
| (Mbps) | (MHz) | of bits | repeats | (MHz) | of bits | repeats |
| 53.3 | 132 | 4 | 3 | 264 | 6 | 2 |
| 80 | 132 | 4 | 2 | 264 | 6 | 2 |
| 106.7 | 132 | 4 | 3 | 264 | 6 | 2 |
| 160 | 132 | 4 | 2 | 264 | 6 | 2 |
| 200 | 132 | 4 | 4 | 264 | 6 | 5 |
| 320 | 132 | 4 | 2 | 264 | 6 | 2 |
| 400 | 132 | 4 | 4 | 264 | 6 | 5 |
| 480 | 132 | 4 | 4 | 264 | 6 | 6 |
| 640 | 264 | 4 | 2 | 264 | 12 | 1 |
| 800 | 264 | 4 | 8 | 264 | 12 | 5 |
| 960 | 264 | 4 | 4 | 264 | 12 | 3 |

The output of the deinterleaver and the output of the depuncturer corresponding to each data rate may be determined as shown in Table 2. In this case, the output of the deinterleaver and the output of the depuncturer depend on a clock, the number of bits, and the number of repeats.

In Table 2, when the number of bits is 6, the coding rate of the convolutional code is ⅓, which means that the number of bits subjected to convolutional coding is 2. Similarly, when the number of bits is 12, the number of bits subjected to convolutional coding is 4.

The output of the deinterleaver corresponds to the input of the depuncturer.

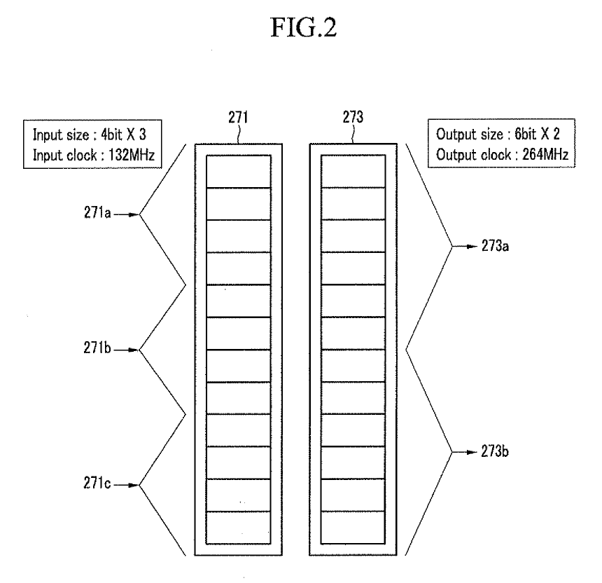

Next, the input and output of the depuncturer according to the exemplary embodiment of the present invention will be described with reference to FIGS. 2, 3, and 4.

FIG. 2 is a diagram illustrating the output and input of the depuncturer when the data rate of the ultra-wideband system according to the exemplary embodiment of the present invention is 53.3 Mbps.

As shown in FIG. 2, the depuncturer 270 according to the exemplary embodiment of the present invention includes a first buffer 271 and a second buffer 273.

The first buffer 271 sequentially receives a first input 271a, a second input 271b, and a third input 271c. The first input 271a, the second input 271b, and the third input 271c correspond to three 4-bit data at a rate of 132 MHz that are output from the deinterleaver 260 when the data rate is 53.3 Mbps, as shown in Table 2.

The second buffer 273 sequentially outputs a first output 273a and a second output 273b. The first output 273a and the second output 273b correspond to two 6-bit data at a rate of 264 MHz that are output from the depuncturer 270 when the data rate is 53.3 Mbps, as shown in Table 2.

In this case, when writing data to the first buffer 271, the depuncturer 270 may output data of the second buffer 273. Then, when the next data is input, the depuncturer 270 may write data to the second buffer 273 and output data of the first buffer 271. In this way, the first buffer 271 and the second buffer 273 may alternately perform reading and writing while data is continuously input.

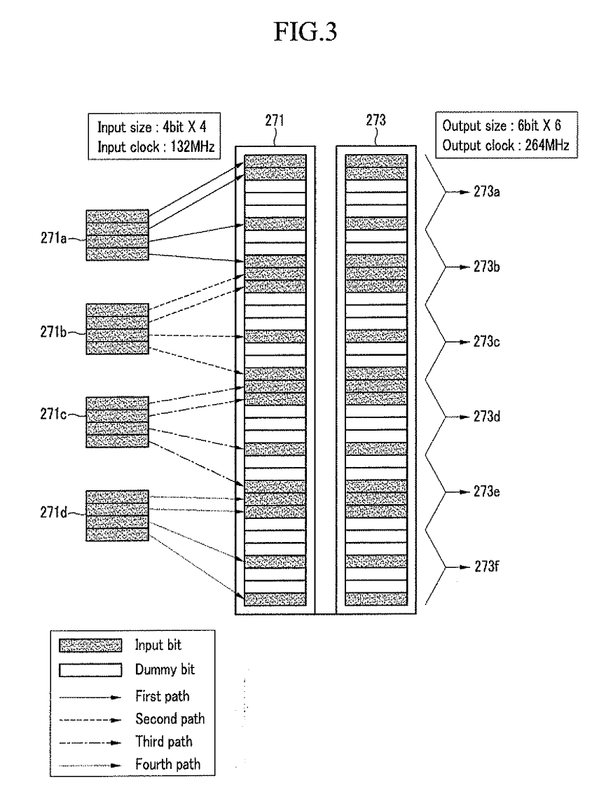

FIG. 3 is a diagram illustrating the output and input of the depuncturer when the data rate of the ultra-wideband system according to the exemplary embodiment of the present invention is 480 Mbps.

As shown in FIG. 3, the depuncturer 270 according to the exemplary embodiment of the present invention includes the first buffer 271 and the second buffer 273.

The first buffer 271 sequentially receives the first input 271a, the second input 271b, the third input 271c, and a fourth input 271d. The first input 271a, the second input 271b, the third input 271c, and the fourth input 271d correspond four 4-bit data at a rate of 132 MHz that are output from the deinterleaver 260 when the data rate is 480 Mbps, as shown in Table 2.

Each of four bits included in each of the first input 271a, the second input 271b, the third input 271c, and the fourth input 271d is written to a portion of the first buffer 271 along any one of the first to fourth paths, and the other portion of the first buffer 271 is filled with dummy bits.

The second buffer 273 sequentially outputs the first output 273a, the second output 273b, a third output 273c, a fourth output 273d, a fifth output 273e, and a sixth output 273f. The first output 273a, the second output 273b, the third output 273c, the fourth output 273d, the fifth output 273e, and the sixth output 273f correspond to six 6-bit data at a rate of 264 MHz that are output from the depuncturer 270 when the data rate is 480 Mbps, as shown in Table 2.

In this case, the first buffer 271 and the second buffer 273 may alternately perform reading and writing while data is continuously input.

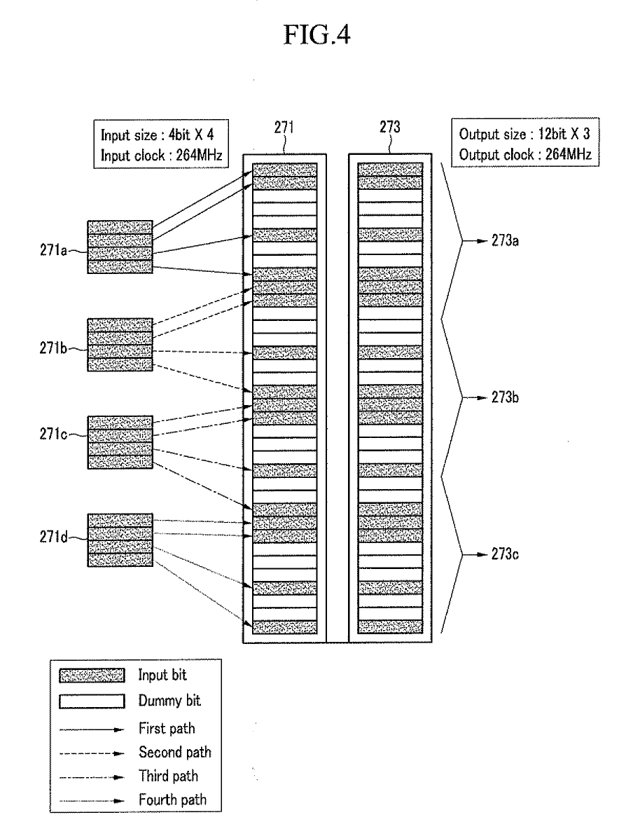

FIG. 4 is a diagram illustrating the output and input of the depuncturer when the data rate of the ultra-wideband system according to the exemplary embodiment of the present invention is 960 Mbps.

As shown in FIG. 4, the depuncturer 270 according to the exemplary embodiment of the present invention includes the first buffer 271 and the second buffer 273.

The first buffer 271 sequentially receives the first input 271a, the second input 271b, the third input 271c, and the fourth input 271d. The first input 271a, the second input 271b, the third input 271c, and the fourth input 271d correspond to four 4-bit data at a rate of 264 MHz that are output from the deinterleaver 260 when the data rate is 960 Mbps, as shown in Table 2.

Each of four bits included in each of the first input 271a, the second input 271b, the third input 271c, and the fourth input 271d is written to a portion of the first buffer 271 along any one of the first to fourth paths, and the other portion of the first buffer 271 is filled with dummy bits.

The second buffer 273 sequentially outputs the first output 273a, the second output 273b, and the third output 273c. The first output 273a, the second output 273b, and the third output 273c correspond to three 12-bit data at a rate of 264 MHz that are output from the depuncturer 270 when the data rate is 960 Mbps, as shown in Table 2.

In this case, the first buffer 271 and the second buffer 273 may alternately perform reading and writing while data is continuously input.

Next, the transmitting/receiving apparatuses of the ultra-wideband system following the MB-OFDM scheme according to the exemplary embodiment of the present invention will be described referring to FIG. 1 again.

The Viterbi decoding unit 280 decodes depunctured data and outputs decoded data including a plurality of bits. When the number of bits of the depunctured data is 6, the Viterbi decoding unit 280 may decode the depunctured data and output 2-bit decoded data. When the number of bits of the depunctured data is 12, the Viterbi decoding unit 280 may decode the depunctured data and output 4-bit decoded data. The Viterbi decoding unit 280 may be called a Viterbi decoding device or a Viterbi decoder.

The descrambler 290 descrambles the decoded data and output source data.

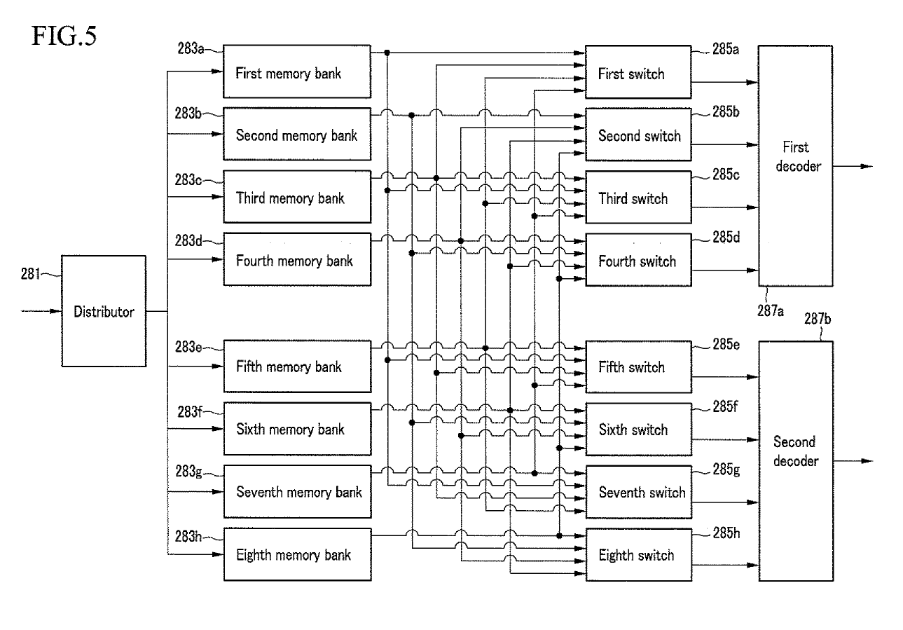

Next, the Viterbi decoding unit according to the exemplary embodiment of the present invention will be described in detail with reference to FIG. 5.

FIG. 5 is a diagram illustrating the structure of the Viterbi decoding unit according to the exemplary embodiment of the present invention.

As shown in FIG. 5, the Viterbi decoding unit 280 according to the exemplary embodiment of the present invention includes a distributor 281, eight memory banks 283a, 283b, 283c, 283d, 283e, 283f, 283g, and 283h, eight switches 285a, 285b, 285c, 285d, 285e, 285f, 285g, and 285h, and two decoders 287a and 287b.

The distributor 281 is connected to the eight memory banks, that is, the first memory bank 283a, the second memory bank 283b, the third memory bank 283c, the fourth memory bank 283d, the fifth memory bank 283e, the sixth memory bank 283f, the seventh memory bank 283g, and the eighth memory bank 283h.

The first switch 285a, the third switch 285c, the fifth switch 285e, and the seventh switch 285g are connected to the first memory bank 283a, the third memory bank 283c, the fifth memory bank 283e, and the seventh memory bank 283g, respectively, and the second switch 285b, the fourth switch 285d, the sixth switch 285f, and the eighth switch 285h are connected to the second memory bank 283b, the fourth memory bank 283d, the sixth memory bank 283f, and the eighth memory bank 283h, respectively.

The distributor 281 receives depunctured data having a plurality of bits, and distributes the plurality of bits included in the depunctured data to the eight memory banks 283a, 283b, 283c, 283d, 283e, 283f, 283g, and 283h. Each of the eight memory banks 283a, 283b, 283c, 283d, 283e, 283f, 283g, and 283h can store L bits, and the distributor 281 sequentially distributes L bits to each memory bank, starting from the first memory bank 283a.

Each of the eight memory banks 283a, 283b, 283c, 283d, 283e, 283f, 283g, and 283h receives L bits from the distributor 281, and transmits the received L bits to some of the eight switches 285a, 285b, 285c, 285d, 285e, 285f, 285g, and 285h. Hereinafter, the L bits stored in one memory bank are referred to as block data.

The first memory bank 283a, the third memory bank 283c, the fifth memory bank 283e, and the seventh memory bank 283g transmit the stored block data to the first switch 285a, the third switch 285c, the fifth switch 285e, and the seventh switch 285g, respectively.

The second memory bank 283b, the fourth memory bank 283d, the sixth memory bank 283f, and the eighth memory bank 283h transmit the stored block data to the second switch 285b, the fourth switch 285d, the sixth switch 285f, and the eighth switch 285h, respectively.

Each of the eight switches 285a, 285b, 285c, 285d, 285e, 285f, 285g, and 285h receives one or more block data, switches the received block data, and outputs a piece of block data.

The first decoder 287a receives the block data from the first switch 285a, the second switch 285b, the third switch 285c, and the fourth switch 285d, processes the received four block data according to a Viterbi decoding algorithm, and outputs two block data.

The second decoder 287b receives the block data from the fifth switch 285e, the sixth switch 285f, the seventh switch 285g, and the eighth switch 285h, and processes the received four block data according to the Viterbi decoding algorithm, and outputs two block data.

The first decoder 287a and the second decoder 287b may correspond to block processing Viterbi decoding units using a block processing Viterbi decoding method. The first decoder 287a and the second decoder 287b may correspond to sliding block Viterbi decoders included in the block processing Viterbi decoding units.

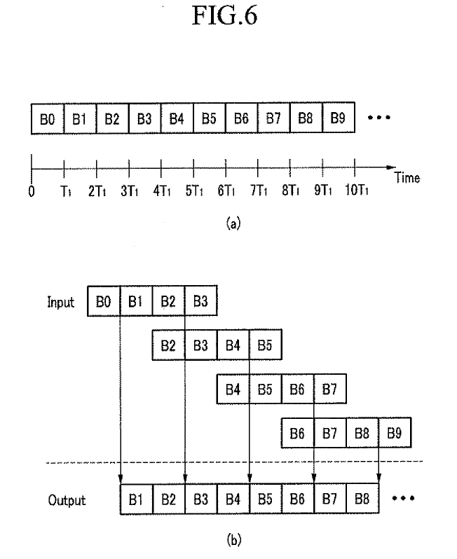

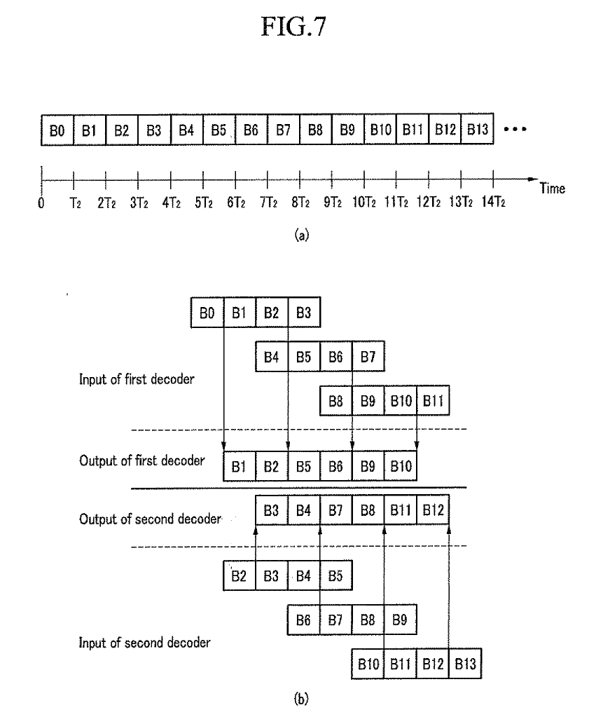

Next, the operation of the Viterbi decoding unit according to the exemplary embodiment of the present invention will be described with reference to FIG. 6 and FIG. 7.

FIGS. 6A and 6B are diagrams illustrating the operation of the Viterbi decoding unit decoding depunctured data when the data rate of the ultra-wideband system according to the exemplary embodiment of the present invention is 480 Mbps or less.

When the data rate is equal to or lower than 480 Mbps, as shown in Table 2, the depuncturer 270 simultaneously outputs 6 bits of a plurality of bits included in the depunctured data, and the Viterbi decoding unit 280 simultaneously receives 6 bits of depunctured data.

The distributor 281 of the Viterbi decoding unit 280 sequentially distributes L bits of the plurality of bits included in the depunctured data to each memory bank from the first memory bank 283a to the eighth memory bank 283h. When the distribution of bits up to the eighth memory bank 283h is completed, the distributor 281 distributes the depunctured data to the first memory bank 283a again.

Then, each of the eight memory banks 283a, 283b, 283c, 283d, 283e, 283f, 283g, and 283h stores the L bits distributed by the distributor 281. The L bits stored in one memory bank are referred to as block data (Bn, n=0, 1, 2, 3, . . . ).

FIG. 6A is a diagram illustrating block data stored in the eight memory banks 283a, 283b, 283c, 283d, 283e, 283f, 283g, and 283h with time.

As shown in FIG. 6A, when a time T₁ is required for one memory bank to write a piece of block data Bn, the first memory bank 283a receives the first block data B0 from the distributor 281 and stores it during the period from 0 to T₁. The second memory bank 283b receives the second block data B1 from the distributor 281 and stores it during the period from T₁ to 2T₁.

The third memory bank 283c stores the third block data B2 during the period from 2T₁ to 3T₁, the fourth memory bank 283d stores the fourth block data B3 during the period from 3T₁ to 4T₁, and the fifth memory bank 283e stores the fifth block data B4 during the period from 4T₁ to 5T₁. In addition, the sixth memory bank 283f stores the sixth block data B5 during the period from 5T₁ to 6T₁, the seventh memory bank 283g stores the seventh block data B6 during the period from 6T₁ to 7T₁, and the eighth memory bank 283h stores the eighth block data B7 during the period from 7T₁ to 8T₁.

Thereafter, the first to eight memory banks 283a to 283h store the next block data in the above-mentioned time order. In this case, each memory bank deletes the previously stored block data and stores new block data.

FIG. 6B is a diagram illustrating the input and output of the first decoder 287a.

As shown in FIG. 6B, first, the first decoder 287a receives the first block data B0, the second block data B1, the third block data B2, and the fourth block data B3, processes the received block data B0, B1, B2, and B3 according to the Viterbi decoding algorithm, and outputs the second block data B1 and the third block data B2.

In this case, after the time 4T₁ has elapsed, the first decoder 287a may receive the first block data B0 stored in the first memory bank 283a, the second block data B1 stored in the second memory bank 283b, the third block data B2 stored in the third memory bank 283c, and the fourth block data B3 stored in the fourth memory bank 283d through the first switch 285a, the second switch 285b, the third switch 285c, and the fourth switch 285d, respectively.

Then, the first decoder 287a receives the third block data B2, the fourth block data B3, the fifth block data B4, and the sixth block data B5, processes the received block data B2, B3, B4, and B5 according to the Viterbi decoding algorithm, and outputs the fourth block data B3 and the fifth block data B4.

In this case, after the time 6T₁ has elapsed, the first decoder 287a may receive the third block data B2 stored in the third memory bank 283c, the fourth block data B3 stored in the fourth memory bank 283d, the fifth block data B4 stored in the fifth memory bank 283e, and the sixth block data B5 stored in the sixth memory bank 283f through the first switch 285a, the second switch 285b, the third switch 285c, and the fourth switch 285d, respectively.

Thereafter, the first decoder 287a receives four block data, processes the four block data according to the Viterbi decoding algorithm, and outputs two block data, using the same method as described above.

The outputs of the four switches 285a, 285b, 285c, and 285d connected to the first decoder 287a with time may be shown as in Table 3.

TABLE 3

| | Time | | | | | | |
|---|---|---|---|---|---|---|---|
| | <4T₁ | 4T₁ | 6T₁ | 8T₁ | 10T₁ | 12T₁ | . . . |
| Switch | OFF | 0 | 1 | 2 | 3 | 0 | . . . |
| selection | | | | | | | |
| Output | | 283a | 283c | 283e | 283g | 283a | . . . |
| of 285a | | | | | | | |
| Output | | 283b | 283d | 283f | 283h | 283b | . . . |
| of 285b | | | | | | | |
| Output | | 283c | 283e | 283g | 283a | 283c | . . . |
| of 285c | | | | | | | |
| Output | | 283d | 283f | 283h | 283b | 283d | . . . |
| of 285d | | | | | | | |

FIGS. 7A and 7B are diagrams illustrating the operation of the Viterbi decoding unit decoding depunctured data when the data rate of the ultra-wideband system according to the exemplary embodiment of the present invention is higher than 480 Mbps.

When the data rate is higher than 480 Mbps, as shown in Table 2, the depuncturer 270 simultaneously outputs 12 bits of a plurality of bits included in the depunctured data, and the Viterbi decoding unit 280 simultaneously receives 12 bits of depunctured data.

The distributor 281 of the Viterbi decoding unit 280 sequentially distributes L bits of the plurality of bits included in the depunctured data to each memory bank from the first memory bank 283a to the eighth memory bank 283h. When the distribution of bits up to the eighth memory bank 283h is completed, the distributor 281 distributes the depunctured data to the first memory bank 283a again.

Then, each of the eight memory banks 283a, 283b, 283c, 283d, 283e, 283f, 283g, and 283h stores the L bits distributed by the distributor 281. The L bits stored in one memory bank is referred to as block data (Bn, n=0, 1, 2, 3, . . . ).

FIG. 7A is a diagram illustrating block data stored in the eight memory banks 283a, 283b, 283c, 283d, 283e, 283f, 283g, and 283h with time.

As shown in FIG. 7A, when a time T₂ is required for one memory bank to write a piece of block data Bn, the first memory bank 283a receives the first block data B0 from the distributor 281 and stores it during the period from 0 to T₂. The second memory bank 283b receives the second block data B1 from the distributor 281 and stores it during the period from T₂ to 2T₂.

The third memory bank 283c stores the third block data B2 during the period from 2T₂ to 3T₂, the fourth memory bank 283d stores the fourth block data B3 during the period from 3T₂ to 4T₂, and the fifth memory bank 283e stores the fifth block data B4 during the period from 4T₂ to 5T₂. In addition, the sixth memory bank 283f stores the sixth block data B5 during the period from 5T₂ to 6T₂, the seventh memory bank 283g stores the seventh block data B6 during the period from 6T₂ to 7T₂, and the eighth memory bank 283h stores the eighth block data B7 during the period from 7T₂ to 8T₂.

Thereafter, the first to eight memory banks 283a to 283h store the next block data in the above-mentioned time order. In this case, each memory bank deletes the previously stored block data and stores new block data.

FIG. 7B is a diagram illustrating the input and output of the first decoder 287a and the second decoder 287b.

As shown in FIG. 7B, first, the first decoder 287a receives the first block data B0, the second block data B1, the third block data B2, and the fourth block data B3, processes the received block data B0, B1, B2, and B3 according to the Viterbi decoding algorithm, and outputs the second block data B1 and the third block data B2.

In this case, after the time 4T₂ has elapsed, the first decoder 287a may receive the first block data B0 stored in the first memory bank 283a, the second block data B1 stored in the second memory bank 283b, the third block data B2 stored in the third memory bank 283c, and the fourth block data B3 stored in the fourth memory bank 283d through the first switch 285a, the second switch 285b, the third switch 285c, and the fourth switch 285d, respectively.

Then, the second decoder 287b receives the third block data B2, the fourth block data B3, the fifth block data B4, and the sixth block data B5, processes the received block data B2, B3, B4, and B5 according to the Viterbi decoding algorithm, and outputs the fourth block data B3 and the fifth block data B4.

In this case, after the time 6T₂ has elapsed, the second decoder 287b may receive the third block data B2 stored in the third memory bank 283c, the fourth block data B3 stored in the fourth memory bank 283d, the fifth block data B4 stored in the fifth memory bank 283e, and the sixth block data B5 stored in the sixth memory bank 283f through the fifth switch 285e, the sixth switch 285f, the seventh switch 285g, and the eighth switch 285h, respectively.

Then, the first decoder 287a receives the fifth block data B4, the sixth block data B5, the seventh block data B6, and the eighth block data B7, processes the received block data B4, B5, B6, and B7 according to the Viterbi decoding algorithm, and outputs the sixth block data B5 and the seventh block data B6.

In this case, after the time 8T₂ has elapsed, the first decoder 287a may receive the fifth block data B4 stored in the fifth memory bank 283e, the sixth block data B5 stored in the sixth memory bank 283f, the seventh block data B6 stored in the seventh memory bank 283g, and the eighth block data B7 stored in the eighth memory bank 283h through the first switch 285a, the second switch 285b, the third switch 285c, and the fourth switch 285d, respectively.

Then, the second decoder 287b receives the seventh block data B6, the eighth block data B7, the ninth block data B8, and the tenth block data B9, processes the plurality of received block data B6, B7, B8, and B9 according to the Viterbi decoding algorithm, and outputs the eighth block data B7 and the ninth block data B8.

In this case, after the time 10T₂ has elapsed, the second decoder 287b may receive the seventh block data B6 stored in the seventh memory bank 283g, the eighth block data B7 stored in the eighth memory bank 283h, the ninth block data B8 stored in the first memory bank 283a, and the tenth block data B9 stored in the second memory bank 283b through the fifth switch 285e, the sixth switch 285f, the seventh switch 285g, and the eighth switch 285h, respectively.

Thereafter, each of the first decoder 287a and the second decoder 287b receives four block data, processes the four block data according to the Viterbi decoding algorithm, and outputs two block data, using the same method as described above.

The outputs of the four switches 285a, 285b, 285c, and 285d connected to the first decoder 287a and the outputs of the four switches 285e, 285f, 285g, and 285h connected to the second decoder 287b may be shown as in Table 4.

(Table 4)

TABLE 4

| Time | <4T₂ | 4T₂ | 6T₂ | 8T₂ | 10T₂ | 12T₂ | 14T₂ | 16T₂ | . . . |
|---|---|---|---|---|---|---|---|---|---|
| Switch | OFF | 0 | 0 | 2 | 2 | 0 | 0 | 2 | . . . |
| selection | | | | | | | | | |
| Output | | 283a | 283a | 283e | 283e | 283a | 283a | 283e | . . . |
| of 285a | | | | | | | | | |
| Output | | 283b | 283b | 283f | 283f | 283b | 283b | 283f | . . . |
| of 285b | | | | | | | | | |
| Output | | 283c | 283c | 283g | 283g | 283c | 283c | 283g | . . . |
| of 285c | | | | | | | | | |
| Output | | 283d | 283d | 283h | 283h | 283d | 283d | 283h | . . . |
| of 285d | | | | | | | | | |
| Switch | OFF | OFF | 3 | 3 | 1 | 1 | 3 | 3 | |
| selection | | | | | | | | | |
| Output | | | 283c | 283c | 283g | 283g | 283c | 283c | |
| of 285e | | | | | | | | | |
| Output | | | 283d | 283d | 283h | 283h | 283d | 283d | |
| of 285f | | | | | | | | | |
| Output | | | 283e | 283e | 283a | 283a | 283e | 283e | |
| of 285g | | | | | | | | | |
| Output | | | 283f | 283f | 283b | 283b | 283f | 283f | |
| of 285h | | | | | | | | | |

The above-described exemplary embodiments of the present invention can be applied to programs that allow computers to execute functions corresponding to the configurations of the exemplary embodiments of the invention or recording media including the programs as well as the method and apparatus. Those skilled in the art can easily implement the applications from the above-described exemplary embodiments of the present invention.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A Viterbi decoding method comprising:
receiving a plurality of block data in time order;
transmitting a first block data group including the plurality of block data;
applying a Viterbi decoding algorithm to the first block data group and outputting some block data of the first block data group;
receiving a plurality of additional block data connected with the plurality of block data in time order;
transmitting a second block data group including the plurality of additional block data and some block data of the first block data group; and
applying the Viterbi decoding algorithm to the second block data group and outputting some block data of the second block data group.

2. The Viterbi decoding method of claim 1,
wherein the receiving of the plurality of block data includes
receiving an even number of block data in time order, and
the receiving of the plurality of additional block data includes
receiving an even number of additional block data in time order.

3. The Viterbi decoding method of claim 2,
wherein the even number of block data is four block data,
the even number of additional block data is two additional block data, and
the second block data group includes two of the four block data and the two additional block data.

4. The Viterbi decoding method of claim 3, wherein the second block data group includes two of the four block data that are received late in time order.

5. The Viterbi decoding method of claim 3,
wherein the outputting of some block data of the first block data group includes
outputting the second block data and third block data of the first block data group that are received in time order.

6. The Viterbi decoding method of claim 3,
wherein the outputting of some block data of the second block data group includes
outputting the second block data and the third block data of the second block data group that are received in time order.

7. The Viterbi decoding method of claim 1, wherein the Viterbi decoding algorithm is a block processing Viterbi decoding algorithm.

8. A Viterbi decoding apparatus that receives data from a depuncturer including two memory buffers and outputting the data from the depuncturer using output clocks which is equal to or higher than input clocks, and performs decoding, the apparatus comprising:
a distributor that receives a plurality of bits from the depuncturer, and distributes the received plurality of bits to each block data unit;
a plurality of memory banks that receive block data corresponding to some of the plurality of bits from the distributor in a predetermined order, and store the received block data;
a plurality of switches that are connected to some of the plurality of memory banks, and output the block data stored in one of the connected memory banks; and
a plurality of decoders that are connected to some of the plurality of switches, receive a plurality of block data from the connected switches, process the plurality of block data according to a Viterbi decoding algorithm, and output some of the plurality of block data.

9. The Viterbi decoding apparatus of claim 8, wherein some or all of the plurality of decoders are used according to the number of bits simultaneously input to the distributor.

10. The Viterbi decoding apparatus of claim 9,
wherein the plurality of memory banks are an even number of memory banks, the plurality of switches are an even number of switches, and
odd-numbered switches of the even number of switches are connected in parallel to odd-numbered memory banks of the even number of memory banks, and even-numbered switches of the even number of switches are connected in parallel to even-numbered memory banks of the even number of memory banks.

11. The Viterbi decoding apparatus of claim 8, wherein the plurality of decoders are sliding block Viterbi decoders using a block processing Viterbi decoding method.

12. The Viterbi decoding apparatus of claim 8,
wherein the plurality of memory banks include eight memory banks,
the plurality of switches include eight switches, and
the plurality of decoders include two decoders.

13. The Viterbi decoding apparatus of claim 12, wherein each of the two decoders has transmission capacity that is half the maximum transmission capacity of the Viterbi decoding apparatus.
